(19) United States
(12) Patent Application Publication
(10) Pub. No.: US 2014/0182814 A1
(43) Pub. Date: Jul. 3, 2014

(54) AIR DUCT

(71) Applicant: HON HAI PRECISION INDUSTRY CO., LTD., New Taipei (TW)

(72) Inventor: HSUAN-I LIN, New Taipei (TW)

(73) Assignee: HON HAI PRECISION INDUSTRY CO., LTD., New Taipei (TW)

(21) Appl. No.: 13/779,756

(22) Filed: Feb. 28, 2013

(30) Foreign Application Priority Data
Dec. 27, 2012 (TW) 101150330

(51) Int. Cl. H05K 7/20

(52) U.S. Cl. CPC H05K 7/20009
USPC 165/80.2

(57) ABSTRACT

An air duct includes a top wall, two sidewalls connected to opposite sides of the top wall, and a board. One of the sidewalls defines an opening extending through a bottom side of the sidewall, and a receiving space communicating with the opening and extending through a top side of the sidewall. The board is slidably received in the receiving space to cover or uncover the opening.

### BACKGROUND

1. Technical Field

The present disclosure relates to an air duct.

2. Description of Related Art

Air ducts often define an opening in a sidewall to accommodate an electronic element mounted on a motherboard. However, when accommodation of an electronic element is not needed, airflow will exhaust through the opening.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of an air duct, wherein the air duct includes a board.

FIG. 2 is an assembled, isometric view of FIG. 1.

FIG. 3 is a cross-sectional view of FIG. 2, taken along the line III-III.

FIG. 4 is an assembled, isometric view of the air duct of FIG. 1 without the board, together with an electronic element.

FIGS. 5 and 6 show other embodiments of an air duct.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

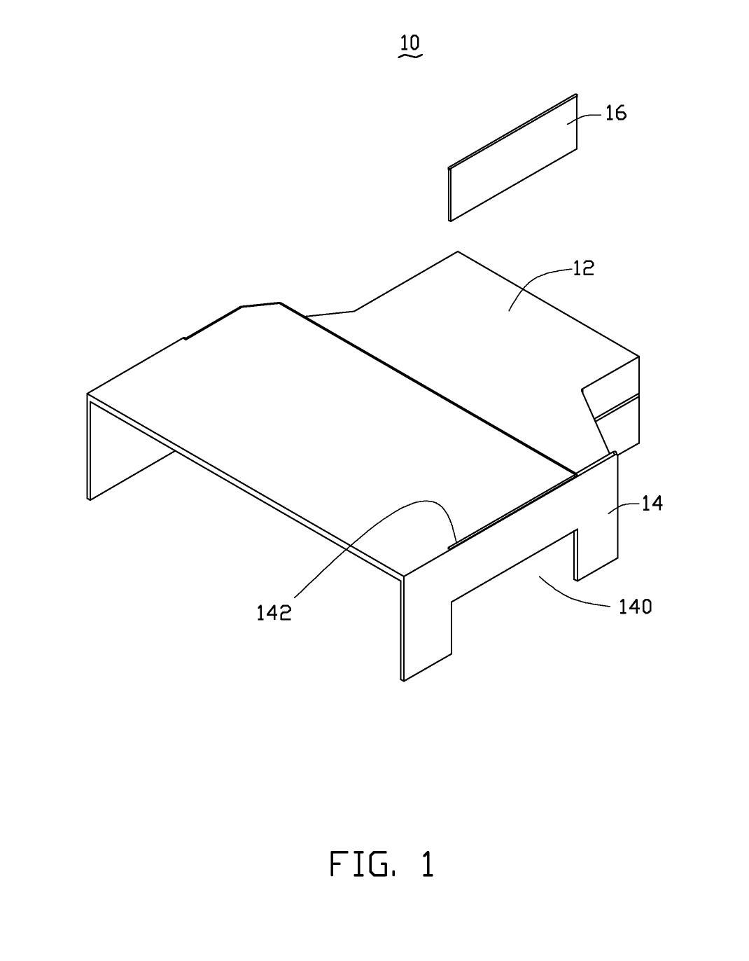

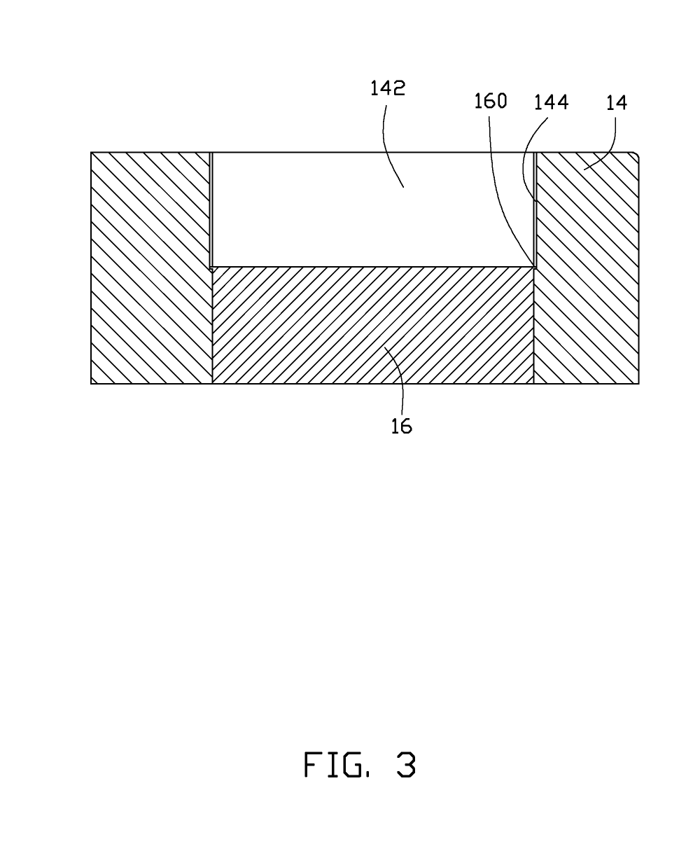

Referring to FIG. 1 and FIG. 3, an embodiment of an air duct 10 includes a top wall 12, two sidewalls 14 perpendicularly extending down from opposite sides of the top wall 12, and a board 16.

One of the sidewalls 14 defines an opening 140 extending through a bottom side of the sidewall 14, and a receiving space 142 positioned above the opening 140. The receiving space 142 extends through a top side of the sidewall 14 and communicates with the opening 140. The receiving space 142 has a length greater than a length of the opening 140. Therefore, two step portions 144 are formed at opposite ends of a bottom side of the receiving space 144. A length of the board 16 is equal to a length of the opening 140.

Two pins 160 extend out from opposite ends of a top side of the board 16.

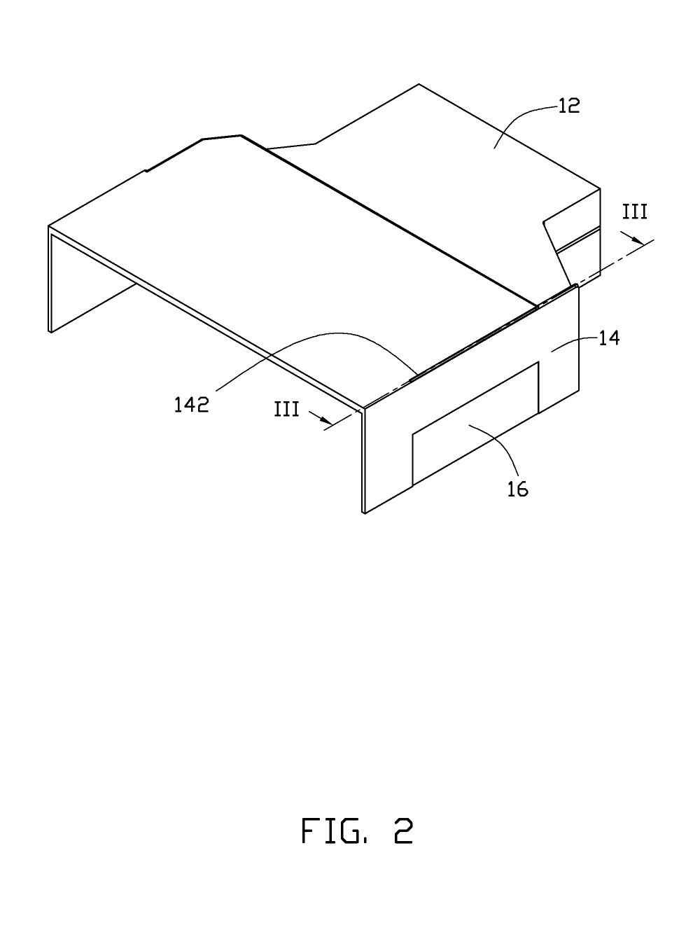

Referring to FIGS. 2 and 3, in assembly, a bottom side of the board 16 slidably extends through the receiving space 142 from the top side of the sidewall 14 and enters the opening 140, until the pins 160 abut against the step portions 144. Therefore, the board 16 completely covers the opening 140.

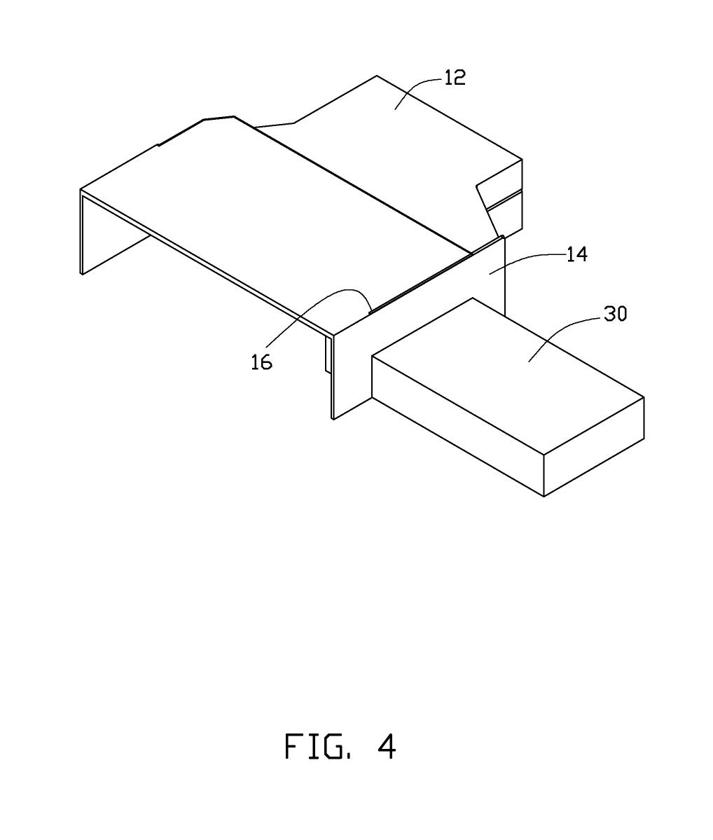

Referring to FIG. 4, in case of accommodating an electronic element 30 in the opening 140, the board 16 is slid upward into the receiving space 142. The electronic element 30 is received in the opening 140. The bottom side of the board 16 contacts a top of the electronic element 30.

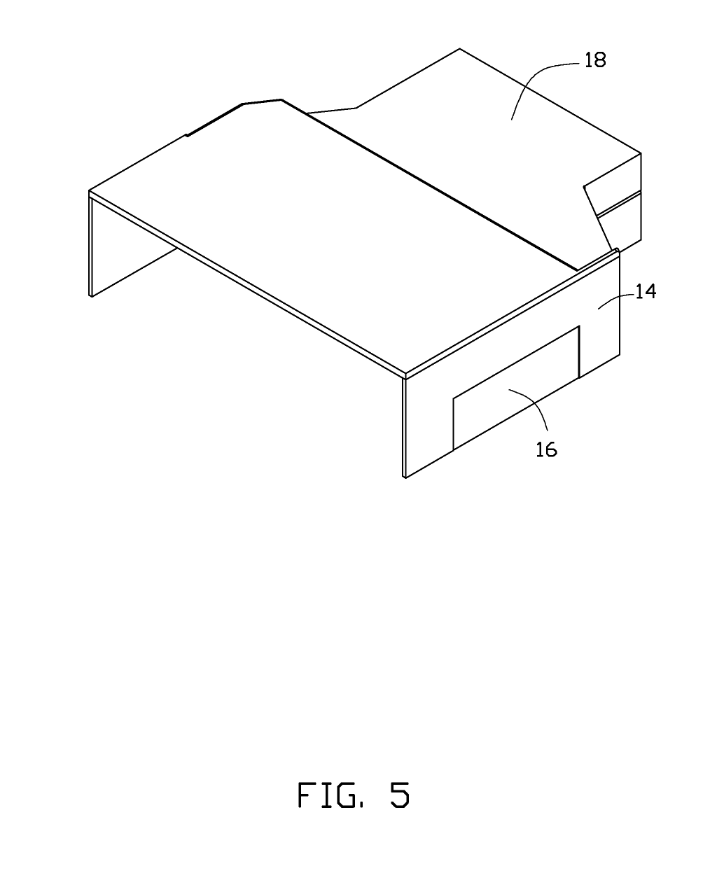

Referring to FIG. 5, in a second embodiment, a top wall 18 of an air duct is detachably mounted between tops of sidewalls 14 of the air duct. After the board 16 enters the receiving space 142, the top wall 18 is mounted to the tops of the sidewalls 14, to cover a top side of the receiving space 142 opposite to an opening 140, to prevent the board 16 from disengaging from the receiving space 142.

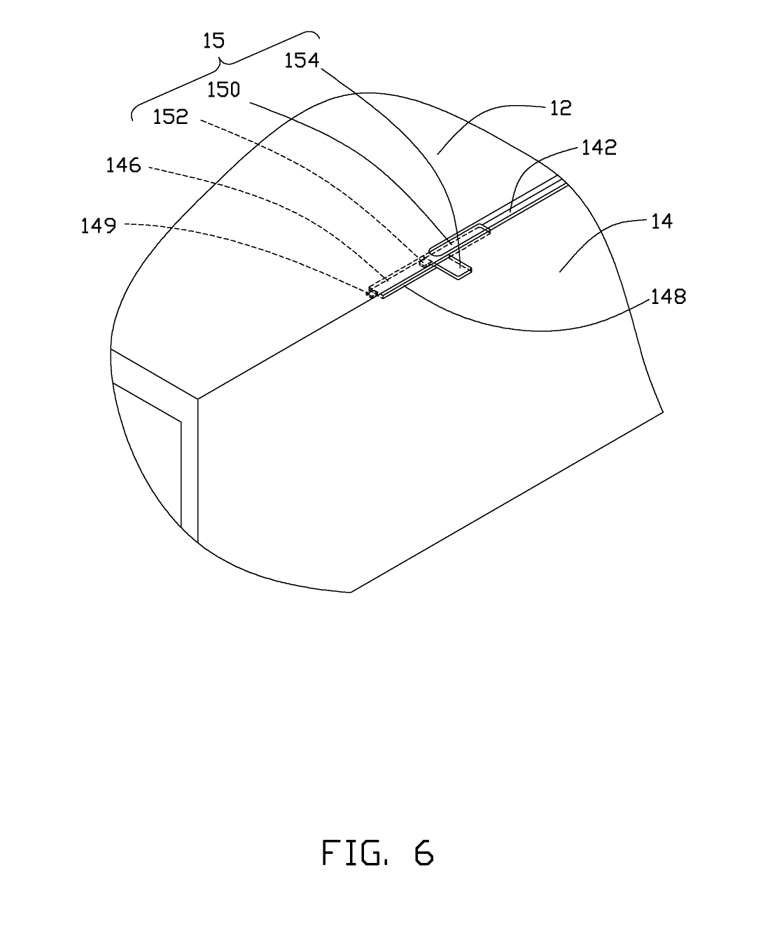

Referring to FIG. 6, in a third embodiment, the sidewall 14 of an air duct defines a receiving space 142, a depressed portion 146 communicating with the receiving space 142, and a slot 148 communicating with the depressed portion 146 and extending through an outer side of the sidewall 14. A recess 149 is defined in an end surface bounding the depressed portion 146 away from the receiving space 142. In the embodiment, the air duct further includes a blocking member 15. The blocking member 15 includes a blocking piece 150 slidably extending through the slot 148 and received in the depressed portion 146, a tab 152 extending from an end of the blocking piece 150 to be engaged in the recess 149, and an operation piece 154 connected to a side of the blocking piece 150 and extending out through the slot 148. A part of the operation piece 154 is slidably received in the slot 148, and can be positioned in a desired position in the slot 148 by friction. The operation piece 154 can be operated to move the blocking piece 150 toward the receiving space 142 to cover a part of a top side of the receiving space 142, to prevent the board 16 from disengaging from the receiving space 142. In another embodiment, the recess 149 and the tab 152 can be omitted.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. An air duct, comprising:
a top wall;
two sidewalls extending down from opposite sides of the top wall; one of the sidewalls defining an opening extending through a bottom side of the sidewall, and a receiving space communicating with the opening and extending through a top side of the sidewall; and
a board slidably received in the receiving space to cover or uncover the opening.

2. The air duct of claim 1, wherein a length of the receiving space is greater than a length of the opening, two step portions are formed at opposite ends of a bottom side of the receiving space adjacent to the opening, two pins extend from opposite ends of the board to abut against the step portions.

3. The air duct of claim 2, wherein the top wall is detachably mounted to top sides of the sidewalls to cover a top side of the receiving space away from the opening.

4. The air duct of claim 2, further comprising a blocking piece, wherein the sidewall defining the opening and the receiving space further defines a depressed portion communicating with the receiving space, the blocking piece is slidably received in the depressed portion, the blocking piece is operable of extending out of the depressed portion and entering the receiving space to block the board.

5. The air duct of claim 4, wherein the sidewall defining the depressed portion further defines a slot extending through an outer surface of the sidewall, an operation portion extends from the blocking piece and extends out through the slot.

6. The air duct of claim 4, wherein the sidewall defining the depressed portion further defines a recess communicating with the depressed portion, a tab extends from the blocking piece to engage in the recess.
